(19) United States
(12) Patent Application Publication
(10) Pub. No.: US 2007/0278692 A1
(43) Pub. Date: Dec. 6, 2007

(54) Structure of semiconductor substrate and molding method

(75) Inventors: Chi-Jang Lo, Hsinchu (TW); Li-chih Fang, Hsinchu (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/444,480

(22) Filed: Jun. 1, 2006

(51) Int. Cl. H01L 23/48

(52) U.S. Cl. 257/774

(57) ABSTRACT

A chip molded onto a substrate with a slot forms a molded semiconductor structure, wherein the chip covers one end of the slot and the other open. This special design leads the mold flow and enhances the semiconductor by a transverse pressure induced by the molding flow as the semiconductor is being molded. Moreover, to arrange the molded semiconductor structures especially in a cavity formed by the top portion die and bottom mold die avoids the flow spill. The special molded semiconductor structure and arrangement enhance the adhesion onto the bottom mold die to upgrade the molding quality.

### 1. FIELD OF THE INVENTION

This present invention relates to a molded semiconductor structure and method, more especially, to a molded semiconductor substrate having one closed end and molding thereof.

### 2. BACKGROUND OF THE RELATED ART

WBGA (Window Ball Grid Array) is one type of packages. Multitudes of wires bond the circuit of a chip and connection pads through the window of a substrate. FIG. 1 is a sectional view of a WBGA illustrating the molded structure in accordance with the prior art. A chip 300 crossing a slot 120 of a substrate 100 adheres onto the substrate 100 by an adhesive resin layer 140. Wires 130 pass through the slot 120 to electrically connect the chip 300 and the connection pads 110 on the substrate 100, and the molding compound 210, 220 seal the chip 300 and the wires 130. An external circuit would connect to the connection pads 110 to conduct the circuit of the chip 300.

A mold has an enclosed cavity consisted of top cavity in top mold die and a bottom cavity in a bottom mold die, in which a package structure is placed. Moreover, a molding gate to lead the molding compound is set on bottom mold die.

The chip 300 adheres onto the bottom mold die and the molding compound flows into the bottom cavity through the molding gate, refer to the FIG. 2 showing the top view of the molded structure illustrating the molding procedure. Mold flow 410 illustrates molding compound under-fills the bottom cavity through the molding gate 400, then the molding compound up-fills the top cavity through the two ends 121 and 122 of the slot 120 to cover the chip 300 after cured. However, when the molding compound passes the slot 120 to up-fill the top cavity, the chip 300 may depart from the bottom mold die to damage the quality of the semiconductor package. Current topic is how to improve the adhesion between chip and mold die.

### SUMMARY OF THE INVENTION

The molding flow induces a transverse pressure when filled into a cavity, and this present invention enhances the adhesion of the chip by imposing the transverse pressure onto chip in bottom mold die.

One of objects of this present invention is to enhance the chip affixed onto the mold. One open end and one closed end are designated to lead the molding flow. The molding flow up-fills the top cavity through the open end and flows toward the closed end to cover the chip. The transverse pressure induced by the molding flow imposes the chip to affix onto the bottom mold die to enhance the adhesion.

Another object of this present invention is to avoid the overflow of molding compound by modifying the arrangement of the chips on the substrate. The slot with one open end on the substrate is designed away from the molding gate to decrease the overflow of the molding compound.

For packaging single chip, the closed end of the slot is near the molding gate. For packaging many chips at the same time, the molded structures near the molding gate has no or small open ends near the molding gate.

### BRIEF DESCRIPTION OF THE DRAWINGS

FIG. 1 shows a sectional view of the molded structure of a prior art.

FIG. 2 shows the arrangement of the molded structures in mold cavity in prior art.

FIG. 3 shows the top schematic view of a molded structure according to an embodiment of this present invention.

FIG. 4 shows the arrangement of single molded structure in mold cavity according to an embodiment of this present invention.

FIG. 5 is a flow chart showing the steps of packaging the semiconductor according to an embodiment of this present invention.

FIG. 6 shows the arrangement of multiple discrete molded structures in mold cavity according to an embodiment of this present invention.

FIG. 7 is a schematic vertical sectional view of multiple molded structures in mold cavity illustrating the mold flow according to an embodiment of this present invention.

FIG. 8 shows the arrangement of multiple continuous molded structures in mold cavity according to an embodiment of this present invention.

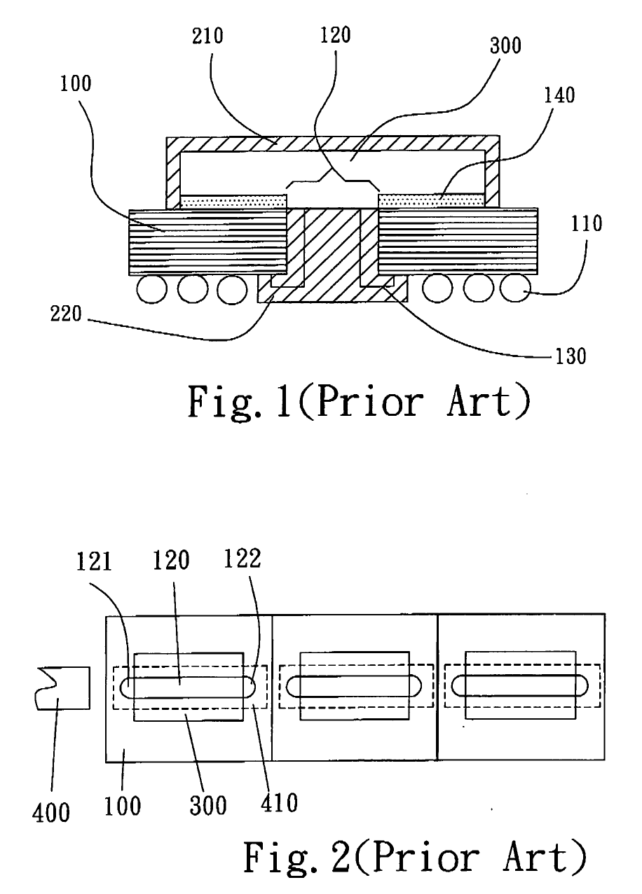

### DETAILED DESCRIPTION OF THE INVENTION

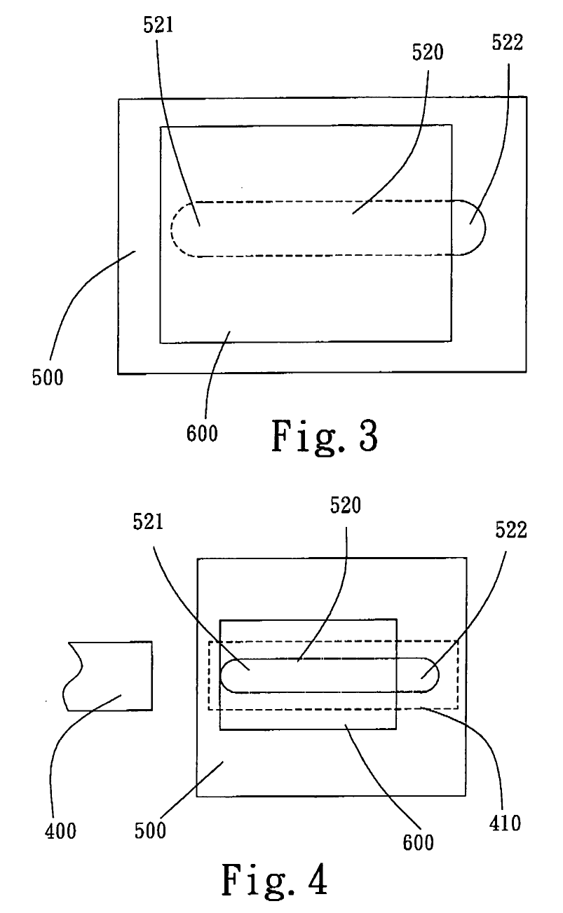

For better understanding, to lead the molding compound from the bottom cavity is assumed, but it can be from the top cavity also. FIG. 3 shows the top schematic view of a molded structure according to an embodiment of this present invention. A chip 600 is set onto a slot 520, such as a bar slot, of the substrate 500 to make an open end 522 exposed by the chip 600 and a closed end 521 covered by the chip 600. The molding compound under-fills the chip 600 and then up-fills the top cavity of a mold to cover the molded structure.

FIG. 4 shows the arrangement of single molded structure in mold cavity according to an embodiment of this present invention to illustrate the molding flow. The open end 522 is away from the molding gate 400 to prevent the overflow of the molding compound. The molding flow 410 under-fills the bottom cavity through the molding gate 400 and then up-fills the top cavity through the open end 522 to flow toward the closed end 521, which may impose transverse pressure onto the molded structure. Accordingly, the package structure is strongly affixed into the bottom

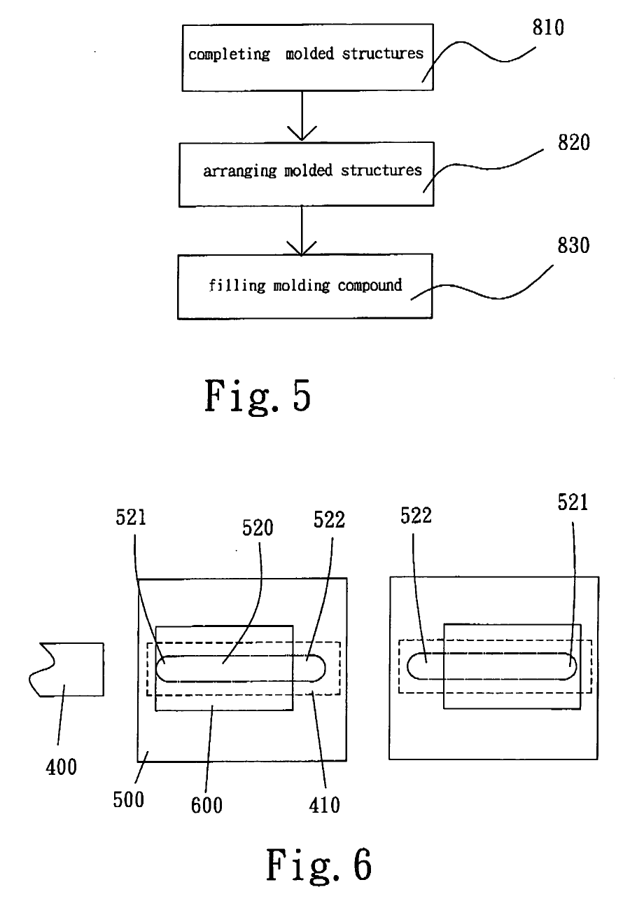

FIG. 5 is a flow chart showing the steps of packaging the semiconductor according to an embodiment of this present invention illustrating the procedures of the packaging.

Step 810: completing the molded structure by affixing a chip onto a substrate with a slot to cover one end of the slot.

Step 820: arranging molded structures by aligning the molded structures with the closed end 521 toward the molding gate.

Step 830: under-filling molding compound into the bottom cavity, then up-filling the top cavity through the open end 522 to cover the molded structure.

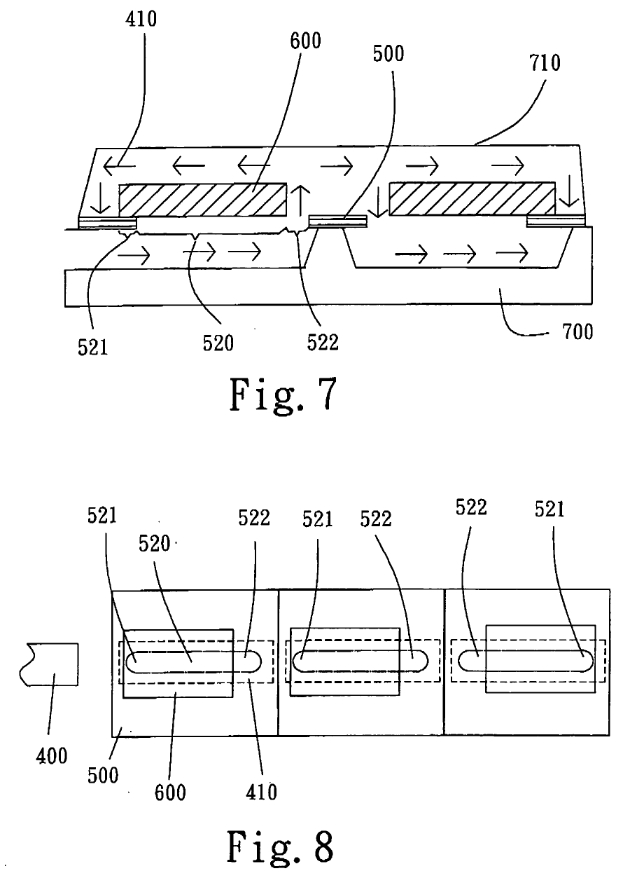

When the molded structures are discrete arrangement, the step of arranging molded structures needs modification, the molded structure nearer the molding gate remains closed end 521 toward the molding gate, but the following structures may be with the open end toward the molding gate. For better understanding, the number of the molded structures is two, but it could be more. FIG. 6 shows two discrete molded structures aligned to the molding gate and FIG. 7 explains the molding flow.

FIG. 6 shows the arrangement of multiple discrete molded structures in mold cavity according to an embodiment of this present invention. The open end 522 of the first molded structure near the molding gate 400 directs toward opposite direction of the molding gate 400, but the open end 522 of the second molded structure directs toward the molding gate 400, where the first molded structure is away from the second molded structure for an example.

FIG. 7 is a schematic vertical sectional view of multiple molded structures in mold cavity illustrating the mold flow according to an embodiment of this present invention. The molding flow 410 under-fills the bottom cavity and then up-fills the top cavity through the open end 522, in which the molding flow may separate two sub-flow: the first sub-flow flows to the closed end of the first molded structure and the second sub-flow to the next molded structure. The transverse pressure induced by the first sub-flow imposes the first chip onto the first substrate, and the second sub-flow flows over the second molded structure to impose the second chip onto the second substrate. Then the molding compound is cured.

The arrangement of the open ends may be modified for the consideration of the successive arrangement of the molded structures. FIG. 8 shows the successive arrangement of multiple continuous molded structures in mold cavity according to an embodiment of this present invention. Three molded structures are aligned successively: the first two molded structures with the open ends 522 toward the molding gate 400 and the third one with the open end away from the molding gate 400.

Although the present invention has been explained in relation to its preferred embodiment, it is to be understood that other modifications and variation can be made without departing the spirit and scope of the invention as claimed.

What is claimed is:

1. A molded semiconductor structure comprising:
a substrate including a slot; and
a chip on said substrate to cover one end of said slot and expose the other end of said slot.

2. A molded semiconductor structure according to claim 1, wherein said slot is a bar slot.

3. A method of packaging semiconductor device, applied to a semiconductor molded structure having a substrate with a slot thereon and a chip covering one end and exposing the other end of said slot, wherein the semiconductor molded structure is affixed in a mold cavity and wherein said mold cavity consisted of a top mold die and a bottom mold die has a molding gate through which molding compound is filled into said molding cavity, said method of packaging semiconductor device comprising:
aligning said molded semiconductor structures in front of said molding gate and said slot parallel to a mold flow led by said molding gate;
arranging said end exposed by said chip away from said molding gate; and
filling molding compound into said molding cavity through said molding gate to cover said molded semiconductor structure and curing said molding compound.

4. A method of packaging semiconductor device according to claim 3, wherein said filling step is to under-fill said molding compound from said bottom cavity or up-fill said molding compound from said bottom cavity.

5. A method of packaging semiconductor device, applied to a molded semiconductor structure having a slot on a substrate and a chip set on the slot with an open end and a closed end, wherein multiple successive molded semiconductor structures are in a mold cavity combined by a top cavity of a top mode die and a bottom cavity of a bottom mold die and the mold cavity has a molding gate to lead molding compound, comprising:
aligning said successive molded semiconductor structures in front of said molding gate along a mold flow parallel to said slot;
separating said molded semiconductor structure nearest molding gate from said rest molded semiconductor structures;
arranging said molded semiconductor structure nearest said molding gate with said open end away from said molding gate; and
filling a molding compound through said molding gate to cover said successive molded semiconductor structures and curing said molding compound.

6. A method of packaging semiconductor device according to claim 5, wherein said filling step is to under-fill said molding compound from said bottom cavity or up-fill said molding compound from said top cavity.

7. A method of packaging semiconductor device, applied to a molded semiconductor structure having a slot on a substrate and a chip set on said slot with an open end and a closed end, wherein successive molded semiconductor structures in a mold cavity and said mold cavity consisted of a top cavity of a top mold die and a bottom cavity of a bottom mold die has a molding gate to lead molding compound, said method of packaging semiconductor device comprising:
aligning said successive molded semiconductor structures and said molding gate along a mold flow parallel to said slot;
arranging said open ends of said two molded semiconductor structure nearer said molding gate away from said molding gate; and
filling molding compound through said molding gate to cover said continuous molded semiconductor structures and curing said molding compound.

8. A method of packaging semiconductor device according to claim 7, wherein said filling step is to up-fill said molding compound from said top cavity or under-fill from said bottom cavity.
